(19) United States
(12) Patent Application Publication
(10) Pub. No.: US 2026/0290475 A1
(43) Pub. Date: Sep. 24, 2026

(54) Data Storage Device and Method for Using Dynamic Delta and Offset for Read Threshold Calibration

(71) Applicant: Sandisk Technologies, Inc., Milpitas, CA (US)

(72) Inventors: Eran Sharon, Rishon Lezion (IL); Alexander Bazarsky, Holon (IL)

(73) Assignee: Sandisk Technologies, Inc., Milpitas, CA (US)

(21) Appl. No.: 19/087,783

(22) Filed: Mar. 24, 2025

(51) Int. Cl. G11C 16/34; G11C 29/52

(52) U.S. Cl. CPC G11C 16/3418; G11C 29/52; G11C 2207/2254

(57) ABSTRACT

In performing a read threshold calibration operation, a series of reads are performed around each read threshold for scanning several options for a specific read threshold. In this process, an offset from a default read threshold can be used, and the voltage distance between two adjacent reads is referred to as a delta. Typically, one offset and delta are applied irrespective of the condition of the memory. The data storage device and method provided herein provide an improvement over this approach by determining a condition of the memory and dynamically selecting an offset and delta based on the determined condition. This can provide savings in both time and power.

### BACKGROUND

Data storage devices often need to support a wide range of operational conditions, such as different program/erase cycles, retention times, and temperatures, which can lead to increased variability between memory dies, blocks, and pages across the different operational conditions. Due to these variations, the read thresholds used for reading a memory page are not fixed and can change significantly as a function of physical location and operational conditions, especially for less-mature, new memory nodes. Reading with inaccurate read thresholds can lead to higher bit error rates, which can degrade performance and quality of service due to decoding failures.

### BRIEF DESCRIPTION OF THE DRAWINGS

FIG. 1A is a block diagram of a data storage device of an embodiment.

FIG. 1B is a block diagram illustrating a storage module of an embodiment.

FIG. 1C is a block diagram illustrating a hierarchical storage system of an embodiment.

FIG. 2A is a block diagram illustrating components of the controller of the data storage device illustrated in FIG. 1A according to an embodiment.

FIG. 2B is a block diagram illustrating components of the data storage device illustrated in FIG. 1A according to an embodiment.

FIG. 3 is a block diagram of a host and a data storage device of an embodiment.

FIG. 4 is a graph of cell voltage distributions of an embodiment.

FIG. 5 is a graph of bit error rate (BER) estimation scan (BES) sense combs of an embodiment.

FIG. 6 is a graph of an embodiment showing voltage shifts of various conditions.

FIG. 7 is a flow chart of a method of an embodiment for performing a read threshold calibration operation.

FIG. 8 is a sigma plot of an embodiment.

### DETAILED DESCRIPTION

The following embodiments generally relate to a data storage device and method for using dynamic delta and offset for read threshold calibration. In one embodiment, a data storage device is provided comprising a memory and one or more processors. The one or more processors, individually or in combination, are configured to: determine at least one condition of a target wordline in the memory, select read threshold calibration operation parameters based on the at least one condition. And perform a read threshold calibration operation using the selected read threshold calibration operation parameters.

In another embodiment, a method is provided that is performed in a data storage device comprising a memory. The method comprises: determining a condition of the memory; selecting parameters of a read threshold calibration operation based on the condition; performing a read threshold calibration operation using the parameters; and reading the memory using a read threshold calibrated by the read threshold calibration operation.

In yet another embodiment, a data storage device is provided comprising: a memory; and means for determining a condition of a target wordline in the memory; selecting read threshold calibration operation parameters based on the condition; and performing a read threshold calibration operation using the selected read threshold calibration operation parameters.

Other embodiments are possible, and each of the embodiments can be used alone or together in combination. Accordingly, various embodiments will now be described with reference to the attached drawings.

### Embodiments

The following embodiments relate to a data storage device (DSD). As used herein, a “data storage device” refers to a non-volatile device that stores data. Examples of DSDs include, but are not limited to, hard disk drives (HDDs), solid state drives (SSDs), tape drives, hybrid drives, etc. Details of example DSDs are provided below.

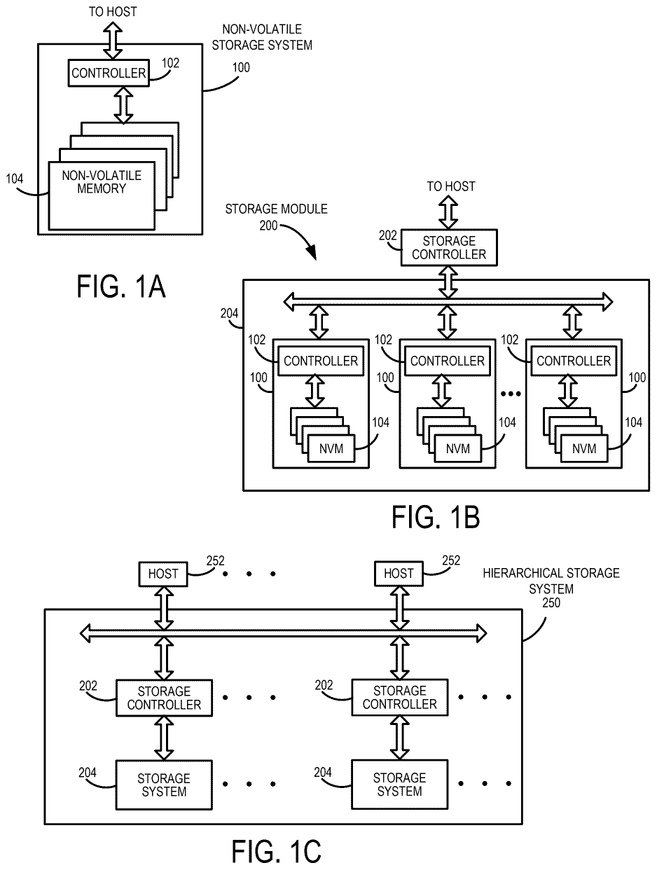

Examples of data storage devices suitable for use in implementing aspects of these embodiments are shown in FIGS. 1A-1C. It should be noted that these are merely examples and that other implementations can be used. FIG. 1A is a block diagram illustrating the data storage device 100 according to an embodiment. Referring to FIG. 1A, the data storage device 100 in this example includes a controller 102 coupled with a non-volatile memory that may be made up of one or more non-volatile memory die 104. As used herein, the term die refers to the collection of non-volatile memory cells, and associated circuitry for managing the physical operation of those non-volatile memory cells, that are formed on a single semiconductor substrate. The controller 102 interfaces with a host system and transmits command sequences for read, program, and erase operations to non-volatile memory die 104. Also, as used herein, the phrase “in communication with” or “coupled with” could mean directly in communication/coupled with or indirectly in communication/coupled with through one or more components, which may or may not be shown or described herein. The communication/coupling can be wired or wireless.

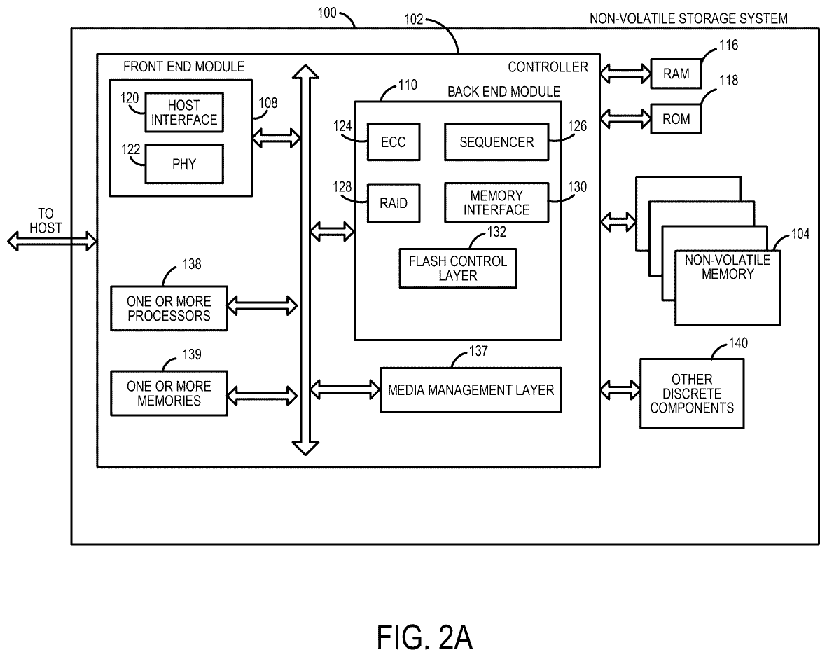

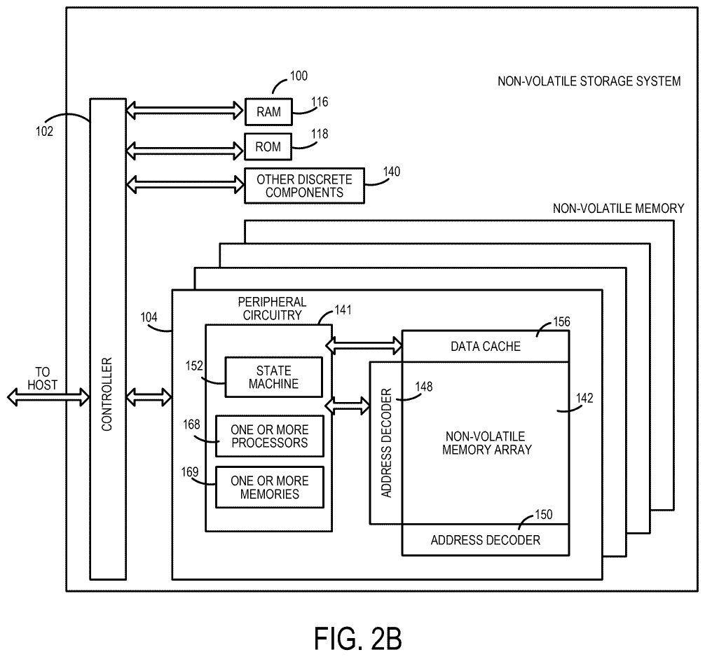

The controller 102 (which may be a non-volatile memory controller (e.g., a flash, resistive random-access memory (ReRAM), phase-change memory (PCM), or magnetoresistive random-access memory (MRAM) controller)) can include one or more components, individually or in combination, configured to perform certain functions, including, but not limited to, the functions described herein and illustrated in the flow charts. For example, as shown in FIG. 2A, the controller 102 can comprise one or more processors 138 that are, individually or in combination, configured to perform functions, such as, but not limited to the functions described herein and illustrated in the flow charts, by executing computer-readable program code stored in one or more non-transitory memories 139 inside the controller 102 and/or outside the controller 102 (e.g., in random access memory (RAM) 116 or read-only memory (ROM) 118). As another example, the one or more components can include circuitry, such as, but not limited to, logic gates, switches, an application specific integrated circuit (ASIC), a programmable logic controller, and an embedded microcontroller.

In one example embodiment, the non-volatile memory controller 102 is a device that manages data stored on non-volatile memory and communicates with a host, such as a computer or electronic device, with any suitable operating system. The non-volatile memory controller 102 can have various functionality in addition to the specific functionality described herein. For example, the non-volatile memory controller can format the non-volatile memory to ensure the memory is operating properly, map out bad non-volatile memory cells, and allocate spare cells to be substituted for future failed cells. Some part of the spare cells can be used to hold firmware (and/or other metadata used for housekeeping and tracking) to operate the non-volatile memory controller and implement other features. In operation, when a host needs to read data from or write data to the non-volatile memory, it can communicate with the non-volatile memory controller. If the host provides a logical address to which data is to be read/written, the non-volatile memory controller can convert the logical address received from the host to a physical address in the non-volatile memory. The non-volatile memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including resistive random-access memory (ReRAM), magnetoresistive random-access memory (MRAM), phase-change memory (PCM), NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC) (e.g., dual-level cells, triple-level cells (TLC), quad-level cells (QLC), etc.) or use other memory cell level technologies, now known or later developed. Also, the memory cells can be fabricated in a two-dimensional or three-dimensional fashion.

The interface between controller 102 and non-volatile memory die 104 may be any suitable flash interface, such as Toggle Mode 200, 400, or 800. In one embodiment, the data storage device 100 may be a card-based system, such as a secure digital (SD) or a micro secure digital (micro-SD) card. In an alternate embodiment, the data storage device 100 may be part of an embedded data storage device.

Although, in the example illustrated in FIG. 1A, the data storage device 100 (sometimes referred to herein as a storage module) includes a single channel between controller 102 and non-volatile memory die 104, the subject matter described herein is not limited to having a single memory channel. For example, in some architectures (such as the ones shown in FIGS. 1B and 1C), two, four, eight or more memory channels may exist between the controller and the memory device, depending on controller capabilities. In any of the embodiments described herein, more than a single channel may exist between the controller and the memory die, even if a single channel is shown in the drawings.

FIG. 1B illustrates a storage module 200 that includes plural non-volatile data storage devices 100. As such, storage module 200 may include a storage controller 202 that interfaces with a host and with data storage device 204, which includes a plurality of data storage devices 100. The interface between storage controller 202 and data storage devices 100 may be a bus interface, such as a serial advanced technology attachment (SATA), peripheral component interconnect express (PCIe) interface, double-data-rate (DDR) interface, or serial attached small scale compute interface (SAS/SCSI). Storage module 200, in one embodiment, may be a solid-state drive (SSD), or non-volatile dual in-line memory module (NVDIMM), such as found in server PC or portable computing devices, such as laptop computers, and tablet computers.

FIG. 1C is a block diagram illustrating a hierarchical storage system. A hierarchical storage system 250 includes a plurality of storage controllers 202, each of which controls a respective data storage device 204. Host systems 252 may access memories within the storage system 250 via a bus interface. In one embodiment, the bus interface may be a Non-Volatile Memory Express (NVMe) or Fibre Channel over Ethernet (FCoE) interface. In one embodiment, the system illustrated in FIG. 1C may be a rack mountable mass storage system that is accessible by multiple host computers, such as would be found in a data center or other location where mass storage is needed.

Referring again to FIG. 2A, the controller 102 in this example also includes a front-end module 108 that interfaces with a host, a back-end module 110 that interfaces with the one or more non-volatile memory die 104, and various other components or modules, such as, but not limited to, a buffer manager/bus controller module that manage buffers in RAM 116 and controls the internal bus arbitration of controller 102. A module can include one or more processors or components, as discussed above. The ROM 118 can store system boot code. Although illustrated in FIG. 2A as located separately from the controller 102, in other embodiments one or both of the RAM 116 and ROM 118 may be located within the controller 102. In yet other embodiments, portions of RAM 116 and ROM 118 may be located both within the controller 102 and outside the controller 102.

Front-end module 108 includes a host interface 120 and a physical layer interface (PHY) 122 that provide the electrical interface with the host or next level storage controller. The choice of the type of host interface 120 can depend on the type of memory being used. Examples of host interfaces 120 include, but are not limited to, SATA, SATA Express, serially attached small computer system interface (SAS), Fibre Channel, universal serial bus (USB), PCIe, and NVMe. The host interface 120 typically facilitates transfer for data, control signals, and timing signals.

Back-end module 110 includes an error correction code (ECC) engine 124 that encodes the data bytes received from the host, and decodes and error corrects the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the memory device 104. In some cases, the RAID module 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. The controller 102 in this example also comprises a media management layer 137 and a flash control layer 132, which controls the overall operation of back-end module 110.

The data storage device 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller are optional components that are not necessary in the controller 102.

FIG. 2B is a block diagram illustrating components of non-volatile memory die 104 in more detail. Non-volatile memory die 104 includes peripheral circuitry 141 and non-volatile memory array 142. Non-volatile memory array 142 includes the non-volatile memory cells used to store data. The non-volatile memory cells may be any suitable non-volatile memory cells, including ReRAM, MRAM, PCM, NAND flash memory cells and/or NOR flash memory cells in a two-dimensional and/or three-dimensional configuration. Non-volatile memory die 104 further includes a data cache 156 that caches data and address decoders 148, 150. The peripheral circuitry 141 in this example includes a state machine 152 that provides status information to the controller 102. The peripheral circuitry 141 can also comprise one or more components that are, individually or in combination, configured to perform certain functions, including, but not limited to, the functions described herein and illustrated in the flow charts. For example, as shown in FIG. 2B, the memory die 104 can comprise one or more processors 168 that are, individually or in combination, configured to execute computer-readable program code stored in one or more non-transitory memories 169, stored in the memory array 142, or stored outside the memory die 104. As another example, the one or more components can include circuitry, such as, but not limited to, logic gates, switches, an application specific integrated circuit (ASIC), a programmable logic controller, and an embedded microcontroller.

In addition to or instead of the one or more processors 138 (or, more generally, components) in the controller 102 and the one or more processors 168 (or, more generally, components) in the memory die 104, the data storage device 100 can comprise another set of one or more processors (or, more generally, components). In general, wherever they are located and however many there are, one or more processors (or, more generally, components) in the data storage device 100 can be, individually or in combination, configured to perform various functions, including, but not limited to, the functions described herein and illustrated in the flow charts. For example, the one or more processors (or components) can be in the controller 102, memory device 104, and/or other location in the data storage device 100. Also, different functions can be performed using different processors (or components) or combinations of processors (or components). Further, means for performing a function can be implemented with a controller comprising one or more components (e.g., processors or the other components described above).

Returning again to FIG. 2A, the flash control layer 132 (which will be referred to herein as the flash translation layer (FTL) handles flash errors and interfaces with the host. In particular, the FTL, which may be an algorithm in firmware, is responsible for the internals of memory management and translates writes from the host into writes to the memory 104. The FTL may be needed because the memory 104 may have limited endurance, may be written in only multiples of pages, and/or may not be written unless it is erased as a block. The FTL understands these potential limitations of the memory 104, which may not be visible to the host. Accordingly, the FTL attempts to translate the writes from host into writes into the memory 104.

The FTL may include a logical-to-physical address (L2P) map (sometimes referred to herein as a table or data structure) and allotted cache memory. In this way, the FTL translates logical block addresses (“LBAs”) from the host to physical addresses in the memory 104. The FTL can include other features, such as, but not limited to, power-off recovery (so that the data structures of the FTL can be recovered in the event of a sudden power loss) and wear leveling (so that the wear across memory blocks is even to prevent certain blocks from excessive wear, which would result in a greater chance of failure).

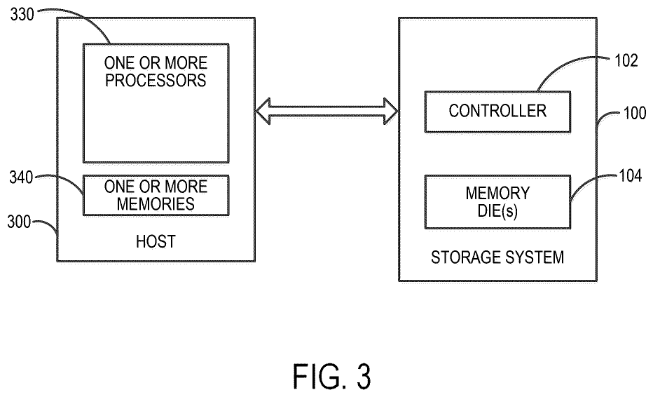

Turning again to the drawings, FIG. 3 is a block diagram of a host 300 and data storage device 100 of an embodiment. The host 300 can take any suitable form, including, but not limited to, a computer, a mobile phone, a tablet, a wearable device, a digital video recorder, a surveillance system, etc. The host 300 in this embodiment (here, a computing device) comprises one or more processors 330 and one or more memories 340. In one embodiment, computer-readable program code stored in the one or more memories 340 configures the one or more processors 330 to perform the acts described herein as being performed by the host 300. So, actions performed by the host 300 are sometimes referred to herein as being performed by an application (computer-readable program code) run on the host 300. For example, the host 300 can be configured to send data (e.g., initially stored in the host's memory 340) to the data storage device 100 for storage in the data storage device's memory 104.

As mentioned above, data storage devices often need to support a wide range of operational conditions, such as different program/erase cycles, retention times, and temperatures, which can lead to increased variability between memory dies, blocks, and pages across the different operational conditions. Due to these variations, the read thresholds used for reading a memory page are not fixed and can change significantly as a function of physical location and operational conditions, especially for less-mature, new memory nodes. Reading with inaccurate read thresholds can lead to higher bit error rates, which can degrade performance and quality of service due to decoding failures.

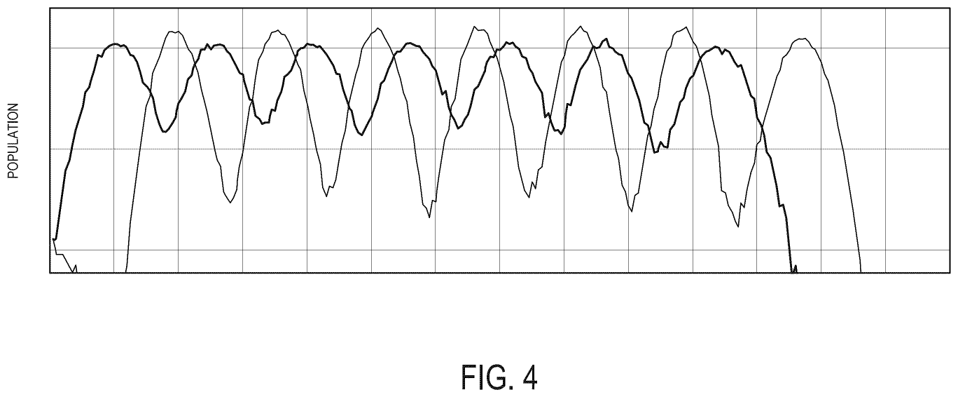

Also, as the quality of service (QoS) requirements from memory controllers become stricter, creative solutions may be needed to reduce the latency of soft bit (SB) decoding and read threshold calibration. Due to process variation, disturb effects, and data retention (DR), the default read thresholds that are used to read from memory in a new (“fresh”) data storage device may not be suitable to read from memory in a “worn” data storage device that sustained such conditions. This is illustrated in FIG. 4, which is a graph of cell voltage distributions of memories in a “fresh” data storage device (“Type 1”) and a “worn” data storage device (“Type 2”) after some significant data retention issues.

When reading at sub-optimal read thresholds, the read page exhibits an increased bit error rate (BER), which can result in longer decoding latency and possibly even decoding failure that triggers a lengthy recovery procedure. This can degrade the quality of service of the data storage device. A reliable, robust, and fast method for read threshold calibration can be used to address this issue. There are different known methods for read threshold calibration. Some of these methods (such as BER estimation scan (BES)) may rely on scanning read thresholds and selecting the ones that minimize the bit error rate (BER) or its syndrome weight (SW) proxy using a dedicated hardware engine. One such method is described in U.S. Pat. No. 9,697,905, which is hereby incorporated by reference. Also, it should be noted that while BES will be used as a read threshold calibration operation in the following examples, other read threshold calibration operations (such as, but not limited to, valley search) can be used.

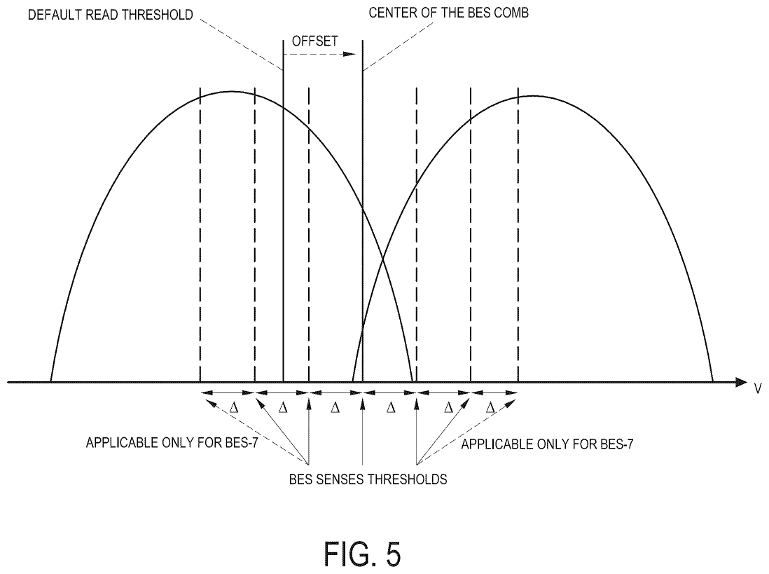

Reading a logical page in memory comprises sensing at several read thresholds and performing an NXOR operation on the sense results to produce the read page. This is usually done internally in the memory. In a BES operation, a series of reads are performed around each read threshold for scanning several options for the specific read threshold. This set of reads is referred to as a comb, and FIG. 5 is a graph showing example BES sense combs. The voltage distance between two adjacent reads is called a “delta,” and as shown in FIG. 5, there may be an offset from the middle of the sense comb with regard to a default read threshold. The entire voltage space that is scanned by BES is called a “BES window.”

Typically, the controller in a data storage device has one delta and offset to apply for all BES activations of the same kind. It may, however, have different parameters for BES operations of different steps in the read-error handling (REH) flow (e.g., BES-coarse with a larger BES window and BES-fine with a smaller BES window). Using a smaller delta has a better impact on result precision but has the disadvantage of having a smaller covered voltage space. If the optimal read threshold is outside the BES window, the results might not be sufficiently good.

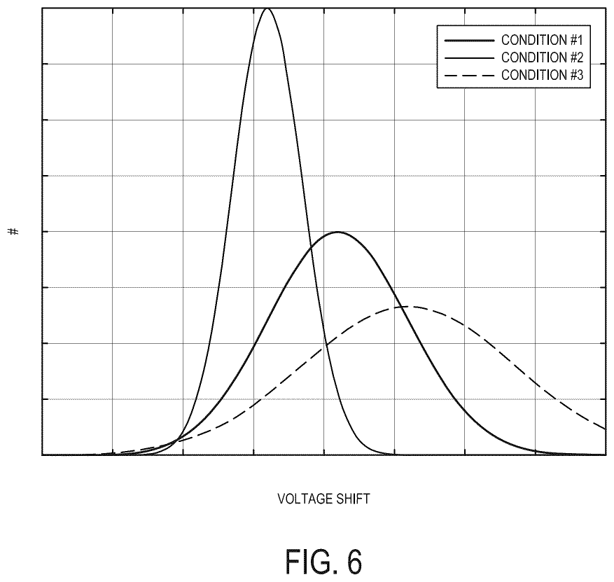

Further, as noted above, different disturb effects, such as data retention, Xtemp, and read disturb (RD), have different impacts on the optimal read thresholds of the memory. For example, while FXtemp (100 C write->−2C read) can move the optimal read thresholds to the negative side, RXtemp (−2C write->100 C read) can move the optimal read thresholds to the positive side. So, there can be different disturb effects on optimal read thresholds per memory state, where FXtemp has the opposite effect of RXtemp with significant impact. As further illustrations, FIG. 6 is a graph of an embodiment showing voltage shifts of various conditions. As can be seen from this discussion, using the same BES delta and offsets for all disturb conditions can be suboptimal, as in order to cover the entire voltage space of all conditions, the BES delta may have to be too large, which can significantly impact the precision of the BES operation.

The following embodiments can address this issue by using dynamic BES deltas and offsets for different disturb conditions. These embodiments also provide for different BES use cases. For example, BES can be operated during the process of read error handling (REH) where there is a read failure of a flash management unit (FMU), which can be the basic write unit of the memory. As another example, BES can also be operated during a time tag update, which is a periodic process to recalibrate read thresholds. In general, using these embodiments can result in better read thresholds, which can reduce BER and power consumption and can increase throughput.

In one embodiment, the controller 102 of the data storage device 100 is configured to use dynamic read threshold calibration parameters (delta and offsets) for different disturb conditions and operating modes. The disturb conditions that affect the memory 104 may be estimated by the controller 102. Further, the controller 102 can use a model to calibrate the optimized delta and offsets according to the different disturb conditions, memory properties, and operating mode conditions, each of which is generally referred to herein as a “memory condition.” Any suitable memory condition can be estimated. Examples of “memory conditions” include, but are not limited to, program temperature (“Prog-Temp”), read temperature (“Read-Temp”), the difference between Prog-Temp of the representative wordlines that are stored in time tag (TT) tables (identifying blocks that are written roughly at the same time and temperature), current Prog-Temp (“X-Temp”), cycling level of the memory, data retention (DR) level which is related to cumulative exposure to high-temperatures and to time elapsed since data refresh, wordline number, and measured BER estimation at a default read temperature (RT).

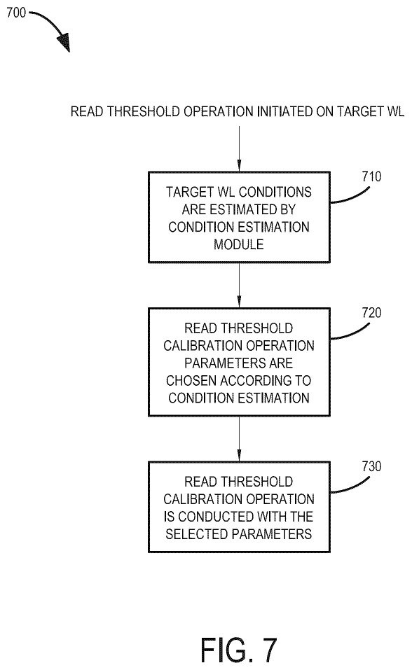

FIG. 7 is a flow chart 700 of a method that can be performed by the controller 102 to implement an embodiment. As shown in FIG. 7, when the controller 102 initiates a read threshold calibration operation on a target wordline in the memory 104, the controller 102 estimates conditions of the target wordline (e.g., using a condition estimation module in the controller 102) (710). Next, the controller 102 chooses read threshold calibration operation parameters (e.g., offset and delta) according to the estimated condition (720). Then, the controller 102 conducts the read threshold calibration operation with the selected parameters (730). So, in this example, once a read threshold calibration operation is initiated on a target wordline, the controller 102 can estimate the condition on the target wordline, either selecting the condition out of a predetermined set or using some continuous function. The read threshold calibration operation parameters may then be chosen, either out of a predetermined set or using some continuous function. The controller 102 can then conduct the read threshold calibration operation with the selected parameters.

As mentioned above, BES can be operated in different use cases, such as during the process of read error handling (REH) where there is a read failure of a flash management unit (FMU) or during time tag update, which is a periodic process to recalibrate read thresholds. Also, using specific BES parameters for a time tag threshold update can be beneficial by reducing BER during the decoding phase. It may also be beneficial to avoid longer processing in advanced decoding phases when the initial decoding fails. For example, having a BER of 0.6% could be decodable with regular hard bit (HB) decoding. However, crossing to 0.8% BER could already be at risk of failing regular HB decoding, triggering the next REH flow phase which can involve much longer processing time.

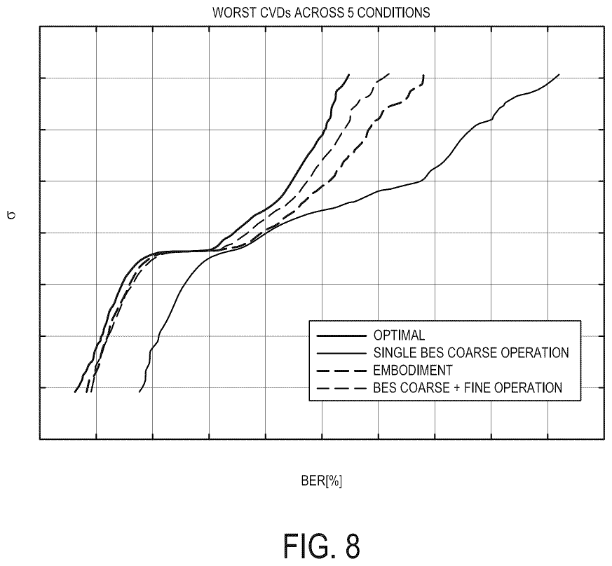

Turning again to the drawings, FIG. 8 is a graph of a sigma plot that illustrates a benefit of this embodiment. In this graph, BER is on the X axis, and the probability of getting the corresponding BER is shown on the Y axis in sigma units. The experiment depicted in this graph was done over B8X4 in five different conditions: FXtemp, RXtemp, RTDR, HTDR 97 hr, HTDR 225 hr. There are four different curves shown. As depicted in the legend in FIG. 8, one curve shows the results with optimal read thresholds, another curve shows the results with a single BES course operation, another curse shows the results using an embodiment described herein, and another curve shows the results of a BES course plus fine operation. FIG. 8 shows that using these embodiments makes it possible to almost reach the results of the double BES5+BES7 operation by using only one BES5 operation with the correct offsets per condition.

The controller 102 ability to estimate a memory condition (e.g., using a condition estimation module in the controller 102) may be based on a machine learning model that can provide an estimation of the memory condition and, with that, the optimized BES parameters based on various parameters (e.g., different NAND conditions, failed bit count (FBC) with default thresholds, default read threshold, etc.). Off-line analysis and training, on-line analysis and training, or a combination of the two can be used.

For the off-line analysis and training approach, a relatively-large amount of state-by-state cell-voltage-distribution (“SbS CVD”) measurements can be collected at different memory conditions, and the optimal BES parameters can be calculated for each measurement. Then, the machine learning model can be trained to couple non-linearly between the input features (e.g., NAND conditions, WL number, SW/BER, etc.) and the BES parameters. During device regular operation, the machine learning model can be applied just before BES operation or in set intervals to determine the current optimal BES parameters. The relevant model parameters can be kept in ROM or SLC, for example. In contrast, the on-line training approach can include continuous data collection during the device's lifetime, where the machine learning model can either be trained or modified based on this dynamic data base. On-line training can continue during the life of the data storage device, and model tuning may be performed.

There are several advantages associated with these embodiments. For example, these embodiments can be used to infer (e.g., from a machine learning model or otherwise) a range in which the optimal read threshold may be found and then perform an additional read threshold calibration operation to acquire the optimal read thresholds. The read thresholds can then be used in reading a wordline from the memory. These embodiments can save time and power when performing read threshold calibration (specifically, in challenging conditions) without increasing the controller/ASIC size. These advantages can be further appreciated as memories scale logically, increasing the number of bits stored per cell. Also, as quality of service requirements become more and more strict especially in high-end enterprise data storage devices, these embodiments can be used to comply with those requirements.

Also, it should be noted that the embodiments presented herein can be used alone or in combination with other read threshold calibration operations. For example, U.S. patent application Ser. No. 17/838,481 and Ser. No. 17/899,073, which are hereby incorporated by reference, describe embodiments for performing read threshold calibration by applying a machine learning prediction model. That model can use, as its inputs, the optimized read thresholds acquired using these embodiments, which may produce better optimized read thresholds or the same optimized read thresholds with less read latency.

Finally, as mentioned above, any suitable type of memory can be used. Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured.

The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and wordlines.

A three-dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements in each column. The columns may be arranged in a two-dimensional configuration, e.g., in an x-z plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three-dimensional structures described but cover all relevant memory structures within the spirit and scope of the invention as described herein and as understood by one of skill in the art.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the embodiments described herein can be used alone or in combination with one another.

What is claimed is:

1. A data storage device comprising:
a memory; and
one or more processors, individually or in combination, configured to:
determine at least one condition of a target wordline in the memory;
select read threshold calibration operation parameters based on the at least one condition; and
perform a read threshold calibration operation using the selected read threshold calibration operation parameters.

2. The data storage device of claim 1, wherein the read threshold calibration operation comprises a bit error rate (BER) estimation scan (BES) and the read threshold calibration operation parameters comprise an offset and a delta.

3. The data storage device of claim 1, wherein the read threshold calibration operation comprises a valley search.

4. The data storage device of claim 1, wherein the at least one condition comprises a program temperature, a read temperature, a difference between program temperatures of representative wordlines, a cycling level, a data retention level, a wordline number, and/or a measured bit error rate (BER) estimation at a default read temperature.

5. The data storage device of claim 1, wherein the selected read threshold calibration operation parameters are selected from a predetermined set of read threshold calibration operation parameters.

6. The data storage device of claim 1, wherein the selected read threshold calibration operation parameters are selected using a continuous function.

7. The data storage device of claim 1, wherein the read threshold calibration operation is performed during a read error handling process.

8. The data storage device of claim 1, wherein the read threshold calibration operation is performed during a time tag update.

9. The data storage device of claim 1, wherein the at least one condition is determined using a machine learning model.

10. The data storage device of claim 9, wherein the machine learning model is trained off-line.

11. The data storage device of claim 9, wherein the machine learning model is trained on-line.

12. The data storage device of claim 1, wherein the one or more processors, individually or in combination, are further configured to use a calibrated read threshold to read the target wordline.

13. The data storage device of claim 1, wherein the memory comprises a three-dimensional memory.

14. In a data storage device comprising a memory, a method comprising:
determining a condition of the memory;
selecting parameters of a read threshold calibration operation based on the condition;
performing a read threshold calibration operation using the parameters; and
reading the memory using a read threshold calibrated by the read threshold calibration operation.

15. The method of claim 14, wherein the read threshold calibration operation comprises a bit error rate (BER) estimation scan (BES) and the parameters comprise an offset and a delta.

16. The method of claim 14, wherein the parameters are selected from a predetermined set.

17. The method of claim 14, wherein the parameters are selected using a continuous function.

18. The method of claim 14, wherein the condition comprises a program temperature, a read temperature, a difference between program temperatures of representative wordlines, a cycling level, a data retention level, a wordline number, and/or a measured bit error rate (BER) estimation at a default read temperature.

19. The method of claim 14, wherein the condition is determined using a machine learning model.

20. A data storage device comprising:
a memory; and
means for
determining a condition of a target wordline in the memory;
selecting read threshold calibration operation parameters based on the condition; and
performing a read threshold calibration operation using the selected read threshold calibration operation parameters.
